(19) United States
(12) Patent Application Publication
(10) Pub. No.: US 2007/0290744 A1
(43) Pub. Date: Dec. 20, 2007

(54) Radio frequency switching circuit, radio frequency switching device, and transmitter module device

(76) Inventors: Masakazu Adachi, Osaka (JP); Tadayoshi Nakatsuka, Osaka (JP)

Correspondence Address: MCDERMOTT WILL & EMERY LLP, 600 13TH STREET, NW, WASHINGTON, DC, 20005-3096, US

(21) Appl. No.: 11/806,303

(22) Filed: May 31, 2007

(30) Foreign Application Priority Data
May 31, 2006 (JP) 2006-152170
Apr. 26, 2007 (JP) 2007-117119

(51) Int. Cl. H03F 1/14

(52) U.S. Cl. 330/51

(57) ABSTRACT

The present invention provides an inexpensive radio frequency switching circuit having desirable radio frequency characteristics over a wide band and desirable endurance against the inflow of a high voltage signal such as an electrostatic surge. Either a negative bias voltage or a positive bias voltage being greater than or equal to 0V and less than or equal to a Schottky forward voltage is used for the control terminals V11 and V12 for controlling FETs 11 to 18 and FETs 21 to 28 so as to turn ON/OFF the path extending from the first input/output terminal P11 to the second input/output terminal P12 and the path extending from the first input/output terminal P11 to the third input/output terminal P13. Thus, it is possible to eliminate the need for DC cut capacitors.

### BACKGROUND OF THE INVENTION

1. Field of the Invention

The present invention relates to a radio frequency switching circuit for switching between a plurality of signal paths in a mobile communications device, or the like, and to a radio frequency switching device and a transmitter module device including such the radio frequency switching circuit combined with a negative bias generation device.

2. Description of the Background Art

In recent years, along with the increase in the functionalities of mobile communications devices, there are strong demands for reducing the size of, and increasing the functionalities of, radio frequency devices for use in terminal devices. Particularly, radio frequency switching devices for switching between antennas are required to achieve low loss characteristics.

FIG. 14 shows an exemplary equivalent circuit of a SPDT (Single-Pole Double-Throw) switching device, being an example of a conventional radio frequency switching device. See, for example, Japanese Laid-Open Patent Publication No. 11-163704 (page 8, FIG. 8).

Referring to FIG. 14, a conventional radio frequency switching circuit 100 includes FETs (depletion type field effect transistors) 11 to 18 and 21 to 28, resistors Rg11 to Rg18, Rg21 to Rg28 and Rs, and capacitors C11 to C13, Cg1 and Cg2 for cutting off DC components.

The FETs 11 to 14 are connected together in series to form a first group of FETs. The FETs 15 to 18 are connected together in series to form a second group of FETs. A first end (closer to the FET 11) of the first group of FETs is connected to a first input/output terminal P11 via the capacitor C11. A second end (closer to the FET 14) of the first group of FETs is connected to a second input/output terminal P12 via the capacitor C12, and is connected to a first end (closer to the FET 15) of the second group of FETs. A second end (closer to the FET 18) of the second group of FETs is grounded via the capacitor Cg1. The gates of the FETs 11 to 14 are connected to a control terminal V12 via the resistors Rg11 to Rg14, respectively. The gates of the FETs 15 to 18 are connected to a control terminal V11 via the resistors Rg15 to Rg18, respectively.

Similarly, the FETs 21 to 24 are connected together in series to form a third group of FETs. The FETs 25 to 28 are connected together in series to form a fourth group of FETs. A first end (closer to the FET 21) of the third group of FETs is connected to the first input/output terminal P11 via the capacitor C11. A second end (closer to the FET 24) of the third group of FETs is connected to a third input/output terminal P13 via the capacitor C13, and is connected to a first end (closer to the FET 25) of the fourth group of FETs. A second end (closer to the FET 28) of the fourth group of FETs is grounded via the capacitor Cg2. The gates of the FETs 21 to 24 are connected to the control terminal V11 via the resistors Rg21 to Rg24. The gates of the FETs 25 to 28 are connected to the control terminal V12 via the resistors Rg25 to Rg28, respectively.

Moreover, the connection point between the second end of the second group of FETs and the second end of the fourth group of FETs is connected to a fixed voltage terminal Vs. The connection point between the first end of the first group of FETs and the first end of the third group of FETs is connected to the fixed voltage terminal Vs via the resistor Rs.

With this configuration, consider a case where 3V is applied to the fixed voltage terminal Vs and the control terminal V11, and 0V is applied to the control terminal V12. Then, the gate-source potential Vgs of each FET in the first and fourth groups of FETs becomes 0V (the FETs are ON), whereas the gate-source potential Vgs of each FET in the second and third groups of FETs becomes −3V (the FETs are OFF). Thus, it is possible to turn ON the path extending from the first signal input/output terminal P11 to the second signal input/output terminal P12, and turn OFF the path extending from the first signal input/output terminal P11 to the third signal input/output terminal P13.

However, the configuration of the conventional radio frequency switching circuit 100 requires DC cut capacitors (C11 to C13, Cg1 and Cg2), and the radio frequency characteristics are deteriorated due to the influence of the frequency characteristics of the DC cut capacitors. Moreover, with a wireless terminal device that requires DC cut capacitors as external components of the radio frequency switching circuit, an extra chip area for accommodating the DC cut capacitors is required in addition to the area for the radio frequency switching circuit. In a case where MIM capacitors are formed as DC cut capacitors on the same semiconductor chip with the FETs in the conventional radio frequency switching circuit 100, since an MIM capacitor has a low ESD resistance (electrostatic resistance), the elements may be broken by, for example, a high voltage of a surge from an antenna terminal of a wireless terminal device, being a cause of post-shipping defects. This also causes defects during production when elements are broken by a high voltage such as a surge applied to an external terminal of the radio frequency switching circuit during the production process.

In order to avoid the problem, Japanese Laid-Open Patent Publication No. 2003-283362 (page 10, FIG. 2) suggests providing capacitors in a multilayer substrate for antenna switching module using a multilayer substrate. However, it has still been difficult to overcome the surge problems for radio frequency switching devices other than those using a multilayer substrate.

### SUMMARY OF THE INVENTION

Therefore, an object of the present invention is to provide an inexpensive radio frequency switching circuit having desirable radio frequency characteristics over a wide band, and desirable endurance against the inflow of a high voltage signal such as an electrostatic surge, and a radio frequency switching device and a transmitter module device using the same.

The present invention is directed to a radio frequency switching circuit for controlling the flow of a radio frequency signal. In order to achieve the above object, a radio frequency switching circuit of the present invention is a radio frequency switching circuit for controlling a flow of a radio frequency signal, including: at least one transistor connected together in series with one another and inserted between two input/output terminals for inputting/outputting the radio frequency signal; a plurality of resistors for grounding a source and a drain of the at least one transistor via a predetermined resistance value; and a plurality of gate resistors for applying a control voltage to a gate of the at least one transistor via a predetermined resistance value, wherein either a negative bias voltage or a positive bias voltage being greater than or equal to 0V and less than or equal to a Schottky forward voltage is applied as the control voltage to turn ON/OFF the flow of the radio frequency signal.

Another radio frequency switching circuit of the present invention is a radio frequency switching circuit for controlling a flow of a radio frequency signal, including: a plurality of transfer transistors, with at least one of the transfer transistors being connected together in series and inserted between a common input/output terminal for inputting/outputting the radio frequency signal and each of first to n-th input/output terminals; a plurality of shunt transistors, with at least one of the shunt transistors being connected together in series and inserted between each of the first to n-th input/output terminals and a ground terminal; a plurality of resistors for grounding sources and drains of the transfer transistors and the shunt transistors via a predetermined resistance value; and a plurality of gate resistors for applying a plurality of different control voltages to gates of the transfer transistors and the shunt transistors via a predetermined resistance value, wherein either a negative bias voltage or a positive bias voltage being greater than or equal to 0V and less than or equal to a Schottky forward voltage is applied as the plurality of different control voltages to turn ON/OFF the flow of the radio frequency signal.

The radio frequency switching circuit may be combined with a negative bias generation circuit for generating a negative bias voltage having a function of increasing the voltage level of the reference voltage applied from outside, thereby realizing a radio frequency switching device. A transmitter module device can be realized by combining the radio frequency switching device further with a power amplifier to which it is necessary to apply the negative bias voltage.

With the radio frequency switching device, the voltage level increasing function can be turned ON/OFF, or the level to which the reference voltage is increased can be selected, based on a path whose connection state is a DC circuit state. Moreover, the level to which the control voltage to be applied to the gate of each transistor is increased can be selected similarly.

Typically, the radio frequency switching device is integrated on a semiconductor substrate, and the transistors are metal-semiconductor field effect transistors or metal-insulator-semiconductor field effect transistors. It is preferred that the semiconductor chip in which the transistors are formed and the negative bias generation circuit are provided in the same package or are formed on the same semiconductor substrate. It is also preferred that the radio frequency switching device is mounted on a multilayer substrate.

According to the present invention, the potential of the source or the drain of the transistor is fixed at a positive bias voltage being greater than or equal to 0V and less than or equal to the Schottky forward voltage, thereby eliminating the need for DC cut capacitors, which are conventionally provided between an external circuit and the first and second input/output terminals. Thus, it is possible to realize desirable radio frequency characteristics over a wide band without being influenced by the frequency characteristics of DC cut capacitors. Moreover, it is possible to avoid the breakdown of the circuit even when there is a flow of a high voltage signal such as an electrostatic surge.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a configuration of a radio frequency switching circuit 1 according to a first embodiment of the present invention;

FIG. 2 shows a configuration of a radio frequency switching circuit 2 according to a second embodiment of the present invention;

FIG. 3 shows a configuration of a radio frequency switching circuit 3 according to a third embodiment of the present invention;

FIG. 4 shows a configuration of a radio frequency switching circuit 4 according to a fourth embodiment of the present invention;

FIG. 5 shows a configuration of a radio frequency switching device 5 according to a fifth embodiment of the present invention;

FIG. 6 is a perspective view showing an example of the inside of a package of the radio frequency switching device 5;

FIG. 7 shows transitions of a control voltage realized by the radio frequency switching device 5;

FIG. 8 shows an exemplary configuration of a transmitter module device using the radio frequency switching device 5;

FIG. 9 shows a configuration of a radio frequency switching device 6 according to a sixth embodiment of the present invention;

FIG. 10 is a perspective view showing an example of the inside of a package of the radio frequency switching device 6;

FIG. 11 shows transitions of a control voltage realized by the radio frequency switching device 6;

FIG. 12 shows changes in voltages applied to the various control terminals of the radio frequency switching device 6;

FIG. 13A is a cross-sectional perspective view showing the inside of a package of a conventional switching module;

FIG. 13B is a cross-sectional perspective view showing the inside of a package of a switching module of the present invention; and

FIG. 14 shows a configuration of a conventional radio frequency switching circuit 100.

### DESCRIPTION OF THE PREFERRED EMBODIMENTS

### First Embodiment

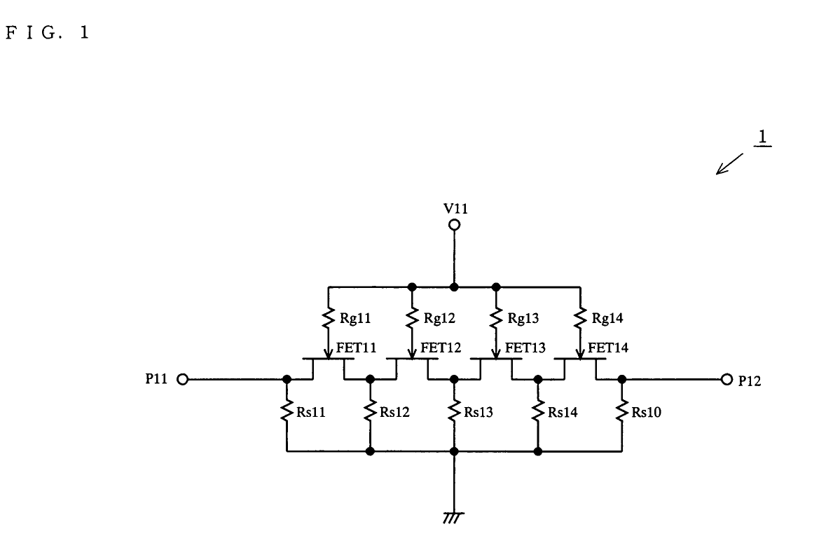

FIG. 1 shows a configuration of a radio frequency switching circuit 1 according to a first embodiment of the present invention. Referring to FIG. 1, the radio frequency switching circuit 1 includes FETs 11 to 14, and resistors Rg11 to Rg14 and Rs10 to Rs14. The FETs 11 to 14 may be depletion type metal-semiconductor field effect transistors (MES-FETs) whose primary material is gallium arsenide (GaAs), or metal-insulator-semiconductor field effect transistors (MIS-FETs) such as MOS-FETs.

The FETs 11 to 14 are connected together in series. The source of the FET 11 is connected to the first input/output terminal P11. The drain of the FET 14 is connected to the second input/output terminal P12. The sources and the drains of the FETs 11 to 14 are grounded via the resistors Rs10 to Rs14 each having a predetermined resistance value. The gates of the FETs 11 to 14 are connected to the control terminal V11 via the resistors Rg11 to Rg14, respectively. The first input/output terminal P11 and the second input/output terminal P12 are each connected to an external circuit such as an antenna circuit or a receiver circuit. A predetermined external voltage is applied to the control terminal V11. The number of FETs connected together in series is not limited to four.

The radio frequency switching circuit 1 is an ON-switch type SPST radio frequency switching circuit, and has a function of turning ON/OFF the path extending from the first input/output terminal P11 to the second input/output terminal P12 according to a control voltage applied to the control terminal V11. The control voltage applied to the control terminal V11 is either “a negative bias voltage”, which turns OFF the path, or “a positive bias voltage being greater than or equal to 0V and less than or equal to the Schottky forward voltage”, which turns ON the path. The Schottky forward voltage depends on the forward voltage Vf of the FET, and is a positive bias voltage of about 1V or less. As the value of the positive bias voltage is closer to the value of the forward voltage Vf, it provides a greater effect as the depletion layer at the metal-semiconductor junction plane becomes narrower. In the present invention, a 0V voltage, capable of turning ON the path, is considered within the definition of a positive bias voltage being less than or equal to the Schottky forward voltage.

With the radio frequency switching circuit 1, a positive bias voltage being greater than 0V and less than or equal to the Schottky forward voltage is applied to the gates of the FETs 11 to 14 in order to turn ON the path extending from the first input/output terminal P11 to the second input/output terminal P12. This brings forth a positive bias voltage state where the gate-source (or gate-drain) voltage Vgs (or Vgd) is less than or equal to the Schottky forward voltage, and the depletion layer is narrowed as compared with a case where 0V is applied to the gates of the FETs 11 to 14, whereby it is possible to improve the radio frequency characteristics such as the insertion loss characteristics and the distortion characteristics along the path extending from the first input/output terminal P11 to the second input/output terminal P12. The Schottky forward voltage as used herein is a Schottky voltage when there is a current flow of 100 μA/m.

In detailed discussions below using specific values, a negative bias voltage is referred to as a “non-actuating voltage”, and a positive bias voltage being greater than or equal to 0V and less than or equal to the Schottky forward voltage is referred to as an “actuating voltage” for the sake of simplicity.

For example, when a non-actuating voltage of −3V is applied to the control terminal V11, the gate-source (or gate-drain) voltage Vgs (or Vgd) of each of the FETs 11 to 14 becomes −3V, thereby turning OFF the path extending from the first input/output terminal P11 to the second input/output terminal P12. When an actuating voltage of 0V is applied to the control terminal V11, the gate-source (or gate-drain) voltage Vgs (or Vgd) of each of the FETs 11 to 14 becomes 0V, thereby turning ON the path extending from the first input/output terminal P11 to the second input/output terminal P12.

As described above, with the radio frequency switching circuit 1 according to the first embodiment of the present invention, the potential of the source or drain of each of the FETs 11 to 14 is fixed at a positive bias voltage being greater than or equal to 0V and less than or equal to the Schottky forward voltage, thereby eliminating the need for DC cut capacitors, which are conventionally provided between an external circuit and the first and second input/output terminals P11 and P12. Thus, it is possible to realize desirable radio frequency characteristics over a wide band without being influenced by the frequency characteristics of DC cut capacitors. Moreover, it is possible to avoid the breakdown of the circuit even when there is a flow of a high voltage signal such as an electrostatic surge.

Moreover, while the radio frequency switching circuit 1 is typically implemented as an integrated circuit on a semiconductor chip, it is not necessary to provide chip capacitors as DC cut capacitors, whereby it is possible to reduce the number of steps in the semiconductor production process and to reduce the semiconductor chip area.

### Second Embodiment

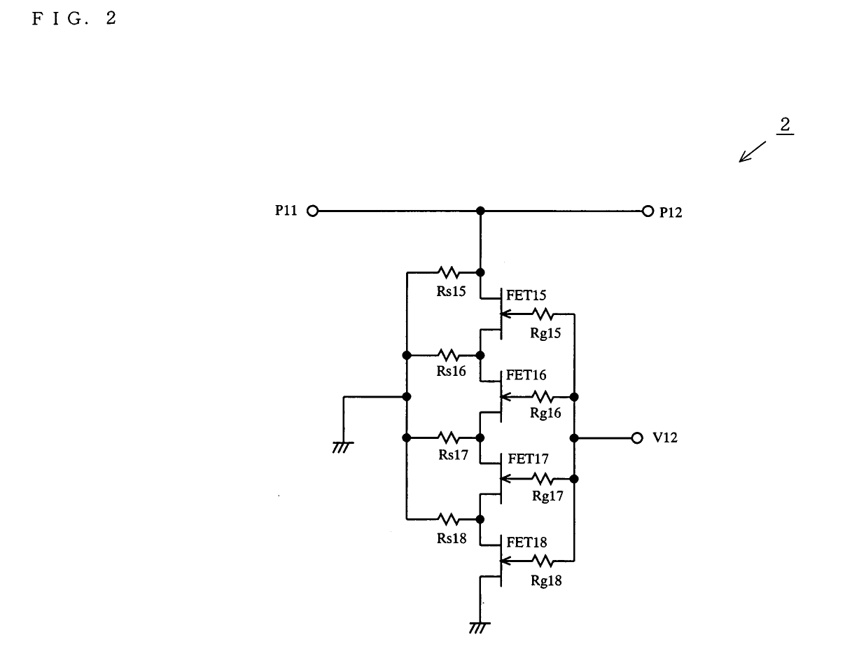

FIG. 2 shows a configuration of a radio frequency switching circuit 2 according to a second embodiment of the present invention. Referring to FIG. 2, the radio frequency switching circuit 2 includes FETs 15 to 18, and resistors Rg15 to Rg18 and Rs15 to Rs18. The FETs 15 to 18 may be MES-FETs, MIS-FETs, or the like.

The FETs 15 to 18 are connected together in series. The source of the FET 15 is connected to the first input/output terminal P11 and the second input/output terminal P12. The drain of the FET 18 is grounded. The sources and the drains of the FETs 15 to 18 are grounded via the resistors Rs15 to Rs18, respectively, having a predetermined resistance value. The gates of the FETs 15 to 18 are connected to the control terminal V12 via the resistors Rg15 to Rg18, respectively. The first input/output terminal P11 and the second input/output terminal P12 are each connected to an external circuit such as an antenna circuit or a receiver circuit. A predetermined external voltage is applied to the control terminal V12. The number of FETs connected together in series is not limited to four.

The radio frequency switching circuit 2 is an OFF-switch type SPST radio frequency switching circuit, and has a function of turning ON/OFF the path extending from the first input/output terminal P11 to the second input/output terminal P12 according to a control voltage applied to the control terminal V12. The control voltage applied to the control terminal V12 is either a negative bias voltage (a non-actuating voltage) and a positive bias voltage being greater than or equal to 0V and less than or equal to the Schottky forward voltage (an actuating voltage).

For example, when a non-actuating voltage of −3V is applied to the control terminal V12, the gate-source (or gate-drain) voltage Vgs (or Vgd) of each of the FETs 15 to 18 becomes −3V, thereby turning ON the path extending from the first input/output terminal P11 to the second input/output terminal P12. When an actuating voltage of 0V is applied to the control terminal V12, the gate-source (or gate-drain) voltage Vgs (or Vgd) of each of the FETs 15 to 18 becomes 0V, thereby turning OFF the path extending from the first input/output terminal P11 to the second input/output terminal P12.

As described above, with the radio frequency switching circuit 2 according to the second embodiment of the present invention, the potential of the source or drain of each of the FETs 15 to 18 is fixed at a positive bias voltage being greater than or equal to 0V and less than or equal to the Schottky forward voltage, thereby eliminating the need for DC cut capacitors, which are conventionally provided between an external circuit and the first and second input/output terminals P11 and P12 and between the FET 18 and the ground. Thus, it is possible to realize desirable radio frequency characteristics over a wide band without being influenced by the frequency characteristics of DC cut capacitors. Moreover, it is possible to avoid the breakdown of the circuit even when there is a flow of a high voltage signal such as an electrostatic surge. The above non-actuating voltage of −3V is an example. Using a higher voltage (in terms of the absolute value thereof), it is possible to improve the linearity and the radio frequency characteristics in a high signal region.

Moreover, while the radio frequency switching circuit 2 is typically implemented as an integrated circuit on a semiconductor chip, it is not necessary to provide chip capacitors as DC cut capacitors, whereby it is possible to reduce the number of steps in the semiconductor production process and to reduce the semiconductor chip area. Particularly, the DC cut capacitor between the FET 18 and the ground is often an MIM capacitor, in which case the ESD resistance of the radio frequency switching circuit is dependent upon the voltage resistance of the MIM capacitor and is very low. By eliminating the presence of an MIM capacitor, the ESD resistance level can be improved 10 times or so.

### Third Embodiment

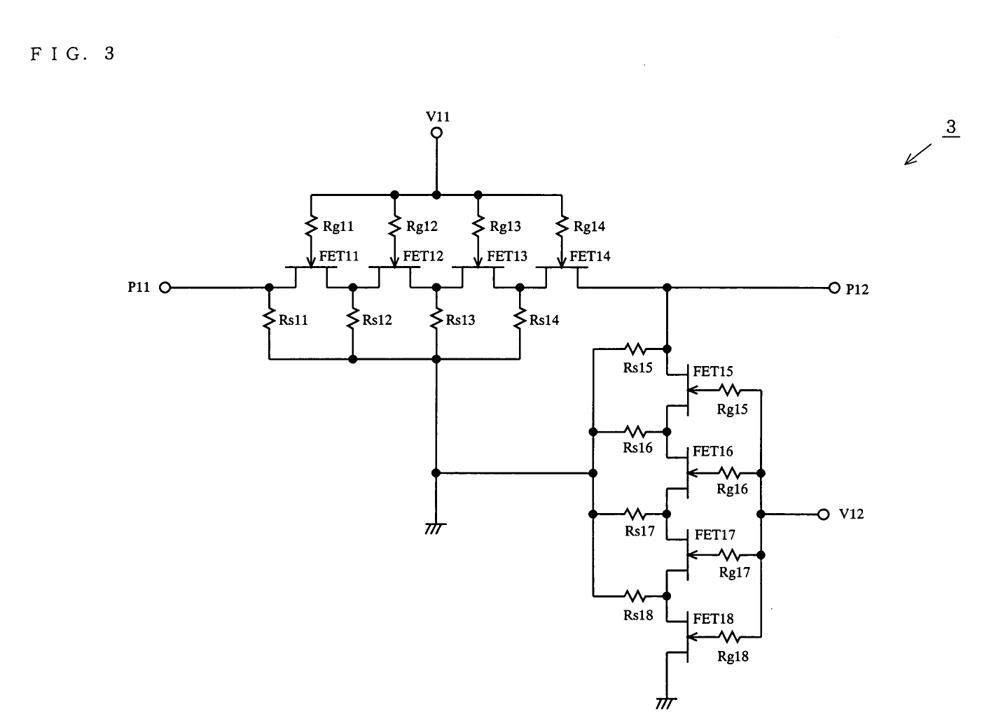

FIG. 3 shows a configuration of a radio frequency switching circuit 3 according to a third embodiment of the present invention. Referring to FIG. 3, the radio frequency switching circuit 3 includes FETs 11 to 18, and resistors Rg11 to Rg18 and Rs11 to Rs18. As can be seen from FIG. 3, the radio frequency switching circuit 3 of the third embodiment is a circuit obtained by combining the radio frequency switching circuit 1 of the first embodiment as a transfer circuit section with the radio frequency switching circuit 2 of the second embodiment as a shunt circuit. The resistor Rs10 is omitted since the resistor Rs15 serves as a shared resistor. It is understood that the number of FETs connected together in series in the transfer circuit section or the shunt circuit section.

Consider a case where an actuating voltage of 0V is applied to the control terminal V11, and a non-actuating voltage of −3V is applied to the control terminal V12. In such a case, each of the FETs (FETs 11 to 14) in the transfer circuit section has its gate-source (or gate-drain) voltage Vgs (or Vgd) forward-biased and is thus ON, whereas each of the FETs (FETs 15 to 18) in the shunt circuit section has its gate-source (or gate-drain) voltage Vgs (or Vgd) reverse-biased and is thus OFF.

Now consider a case where a non-actuating voltage of −3V is applied to the control terminal V11 and an actuating voltage of 0V is applied to the control terminal V12. In such a case, each FET in the transfer circuit section is OFF, and each FET in the shunt circuit section is ON.

When each FET in the transfer circuit section is ON, each FET in the shunt circuit section is OFF. Therefore, a signal inputted from an antenna connected to the first input/output terminal P11, for example, passes through the transfer circuit section and is transmitted to the receiver circuit section connected to the second input/output terminal P12. Then, since each FET in the shunt circuit section is OFF, no signal is transmitted to the shunt circuit section. Conversely, when each FET in the transfer circuit section is OFF, no signal can pass through the transfer circuit section. Even if a large signal is inputted from an antenna and the signal leaks to the transfer circuit section being OFF, the leak signal is released to GND but is not transmitted to the receiver circuit section since the shunt circuit section is ON.

As described above, with the radio frequency switching circuit 3 according to the third embodiment of the present invention, a circuit obtained by combining an ON-switch type SPST radio frequency switching circuit with an OFF-switch type SPST radio frequency switching circuit can be made to function as a radio frequency receiver switching device by appropriately controlling the control terminals V11 and V12.

### Fourth Embodiment

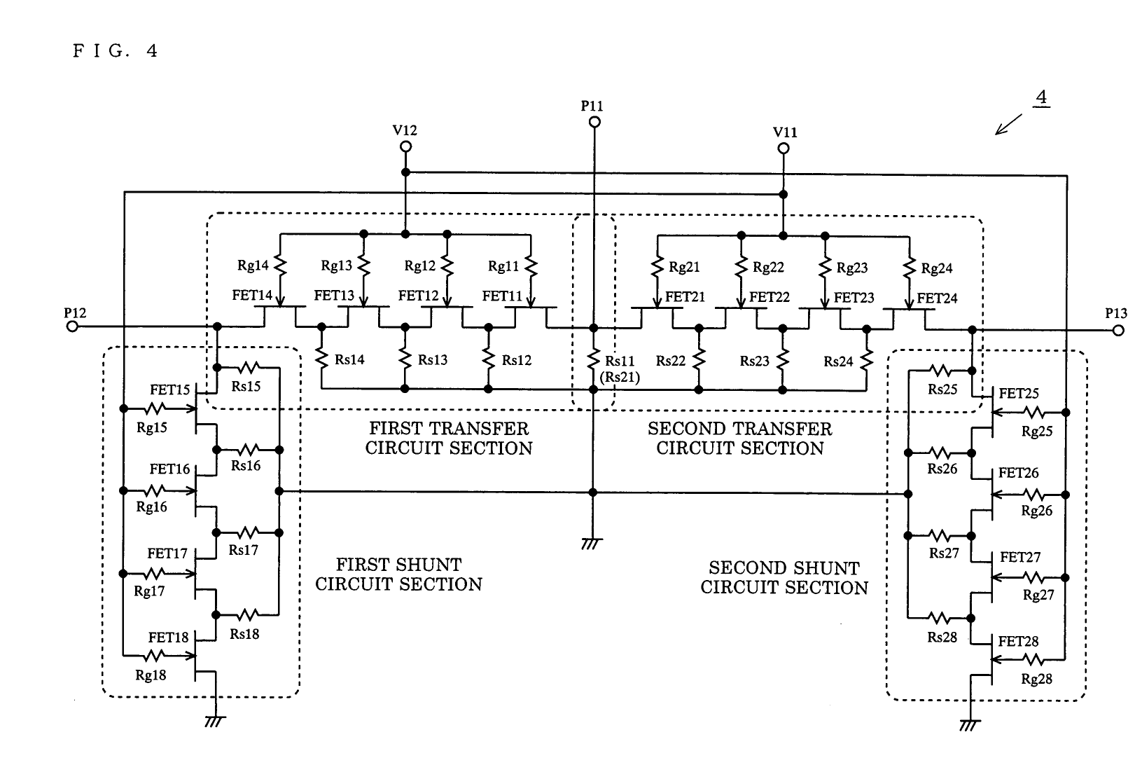

FIG. 4 shows a configuration of a radio frequency switching circuit 4 according to a fourth embodiment of the present invention. Referring to FIG. 4, the radio frequency switching circuit 4 includes FETs 11 to 18 and 21 to 28, and resistors Rg11 to Rg18, Rg21 to Rg28, Rs11 to Rs18 and Rs22 to Rs28. As can be seen from FIG. 4, the radio frequency switching circuit 4 of the fourth embodiment is obtained by using two of the radio frequency switching circuits 3 of the third embodiment connected together in parallel with the first input/output terminal P11 being a shared terminal therebetween. The resistor Rs21 is omitted since the resistor Rs11 serves as a shared resistor.

The FETs 11 to 14, the resistors Rg11 to Rg14 and Rs11 to Rs14 together form a first transfer circuit section. The FETs 15 to 18, the resistors Rg15 to Rg18 and Rs15 to Rs18 together form a first shunt circuit section. The FETs 21 to 24, the resistors Rg21 to Rg24 and Rs21 to Rs24 together form a second transfer circuit section. The FETs 25 to 28 and the resistors Rg25 to Rg28 and Rs25 to Rs28 together form a second shunt circuit section.

The control voltages applied to the control terminals V11 and V12 (a negative bias voltage and a positive bias voltage being greater than or equal to 0V and less than or equal to the Schottky forward voltage) are controlled so that the transfer circuit section of one of the radio frequency switching circuits 3 and the shunt circuit section of the other one of the radio frequency switching circuits 3 are both ON.

As described above, with the radio frequency switching circuit 4 according to the fourth embodiment of the present invention, it is possible to improve the radio frequency characteristics over a wide band and to realize desirable distortion characteristics when large signals are passing therethrough and a reduction in the power consumption when small signals are passing therethrough. Moreover, it is possible to avoid the breakdown of the circuit even when there is a flow of a high voltage signal such as an electrostatic surge.

### Fifth Embodiment

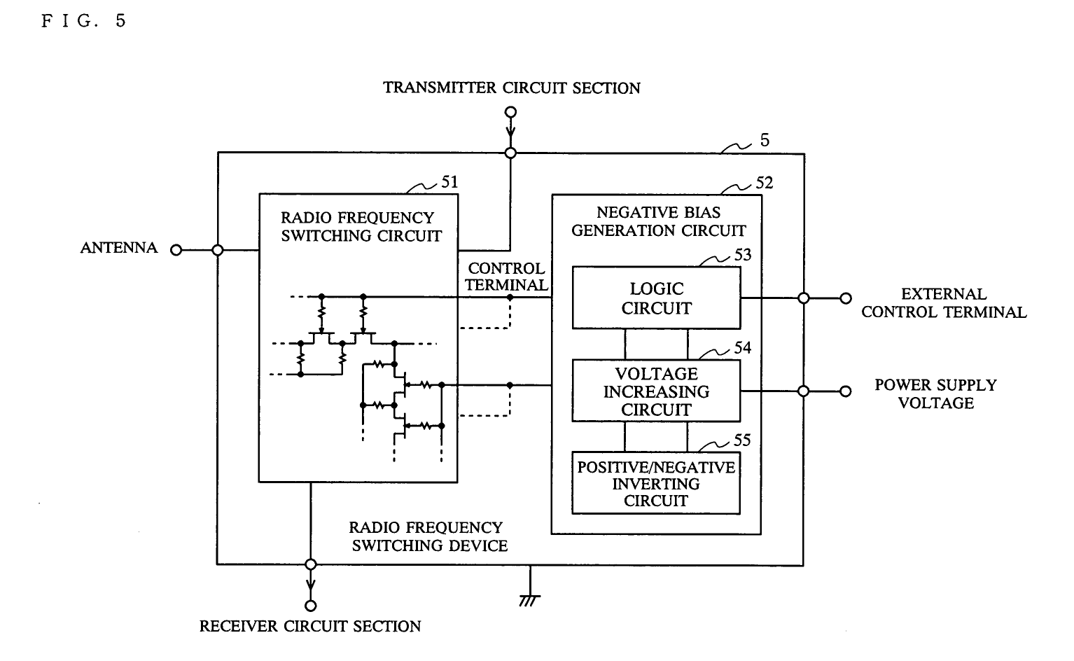

FIG. 5 shows a configuration of a radio frequency switching device 5 according to a fifth embodiment of the present invention. Referring to FIG. 5, the radio frequency switching device 5 includes a radio frequency switching circuit 51 and a negative bias generation circuit 52, which includes a logic circuit 53, a voltage increasing circuit 54 and a positive/negative inverting circuit 55 integrated together.

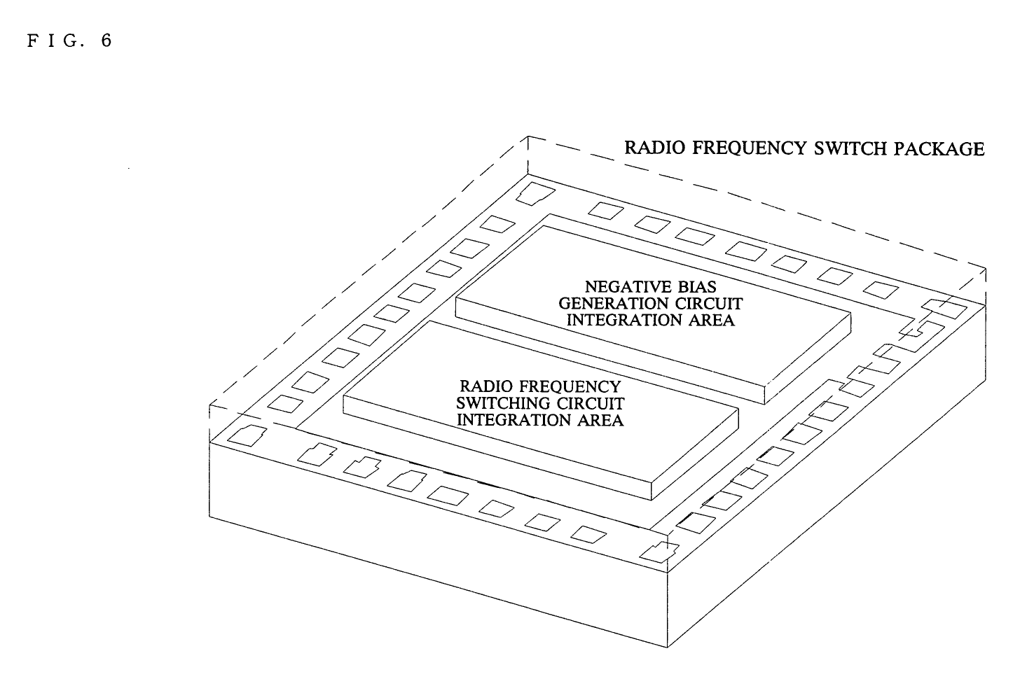

FIG. 6 is a perspective view showing an example of the inside of a package of the radio frequency switching device 5. As shown in FIG. 6, the radio frequency switching device 5 includes, in the form of bare chips packaged together, a semiconductor chip obtained by integrating the radio frequency switching circuit 51 and a semiconductor chip obtained by integrating the negative bias generation circuit 52.

The radio frequency switching circuit 51 employs the radio frequency switching circuit 4 of the fourth embodiment. The negative bias generation circuit 52 uses the external control voltage applied to the external control terminal so as to control the control voltages applied to the control terminals V11 and V12 connected to the transfer circuit sections and the shunt circuit sections of the radio frequency switching circuit 51. The control terminal V11 is connected to the gates of the FETs of the first transfer circuit section and the second shunt circuit section. The control terminal V12 is connected to the gates of the FETs of the second transfer circuit section and the first shunt circuit section.

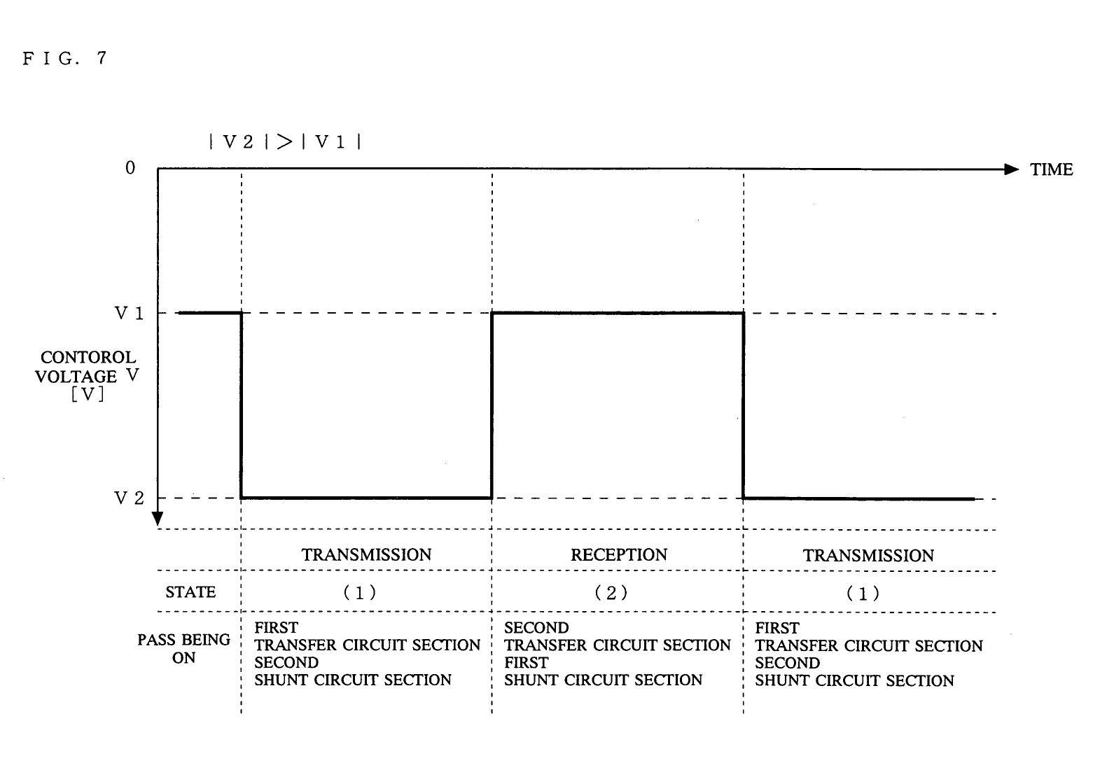

FIG. 7 shows transitions of a control voltage realized by the radio frequency switching device 5.

For example, where 3V is applied as the power supply voltage and 3V is applied as the external control voltage, the voltage increasing circuit 54 is ON, and the OFF control voltage of the control voltage is in a state (1) shown in the figure. For example, where an actuating voltage of 0V and a non-actuating voltage of −6V are applied to the control terminals V11 and V12, respectively, each of the FETs in the first transfer circuit section and the second shunt circuit section has its gate-source (or gate-drain) voltage Vgs (or Vgd) forward-biased and is thus ON, whereas each of the FETs in the second transfer circuit section and the first shunt circuit section has its gate-source (or gate-drain) voltage Vgs (or Vgd) strongly reverse-biased and is thus OFF.

In such a state, a signal inputted from a transmitter circuit section connected to the second input/output terminal P12 is transmitted to an antenna connected to the first input/output terminal P11 through the first transfer circuit section. Since the FETs in the first shunt circuit are OFF, the signal is not transmitted to the first shunt circuit section. Moreover, the second transfer circuit section is OFF and the second shunt circuit section is ON. Therefore, even if a signal leaks to the second transfer circuit section, the leak signal is released to GND but is not transmitted to the receiver circuit section since the second shunt circuit section is ON. Since the FETs of the first shunt circuit section and the second transfer circuit section are strongly reverse-biased, it is possible to realize desirable distortion characteristics with desirable linearity.

Conversely, where 3V is applied as the power supply voltage and 0V is applied as the external control voltage, for example, the voltage increasing circuit 54 is OFF and the OFF control voltage of the control voltage is in a state (2) shown in the figure. For example, where a non-actuating voltage of −3V and an actuating voltage of 0V are applied to the control terminals V11 and V12, respectively, each of the FETs in the first transfer circuit section and the second shunt circuit section has its gate-source (or gate-drain) voltage Vgs (or Vgd) reverse-biased and is thus OFF, whereas each of the FETs in the second transfer circuit section and the first shunt circuit section has its gate-source (or gate-drain) voltage Vgs (or Vgd) forward-biased and is thus ON.

The voltage increasing circuit 54 has a disadvantage in that the current consumption thereof is as high as 200 μA in order to increase the voltage. However, when the signal passing therethrough is a low signal as in a signal-receiving operation, it is not needed to be strongly reverse-biased. Therefore, the voltage-increasing function of the circuit may be turned OFF by logic control so that the current consumption thereof can be reduced to be 1 μA or less.

As described above, with the radio frequency switching device 5 according to the fifth embodiment of the present invention, it is possible to eliminate the need for DC cut capacitors, which are needed in conventional configurations. Therefore, it is possible to realize desirable radio frequency characteristics over a wide band without being influenced by the frequency characteristics of DC cut capacitors. Particularly, it is possible to realize stable isolation characteristics.

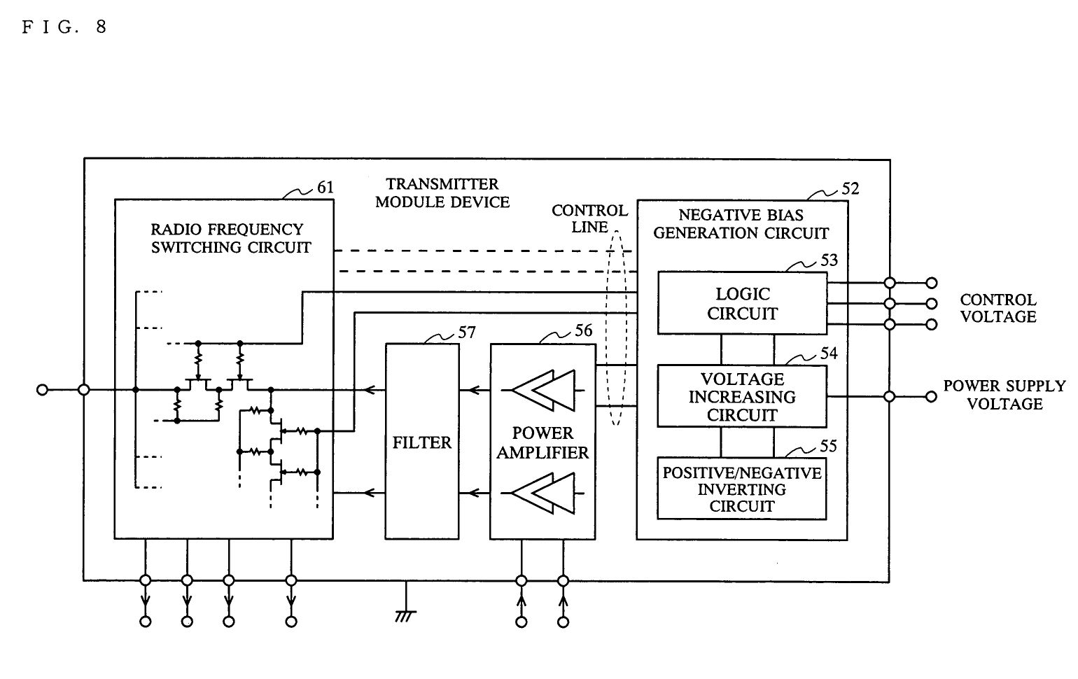

FIG. 8 shows an exemplary configuration of a transmitter module device using the radio frequency switching device 5 as described above. The transmitter module device is obtained by further adding, to the radio frequency switching device 5, a power amplifier 56 using depletion type FETs, and a filter 57 for attenuating the harmonic distortion occurring in the power amplifier 56. With this configuration, a single power supply can be shared between the power amplifier 56 and the radio frequency switching device 5, which both need a negative bias power supply. Therefore, it is possible to easily realize a small transmitter module device.

### Sixth Embodiment

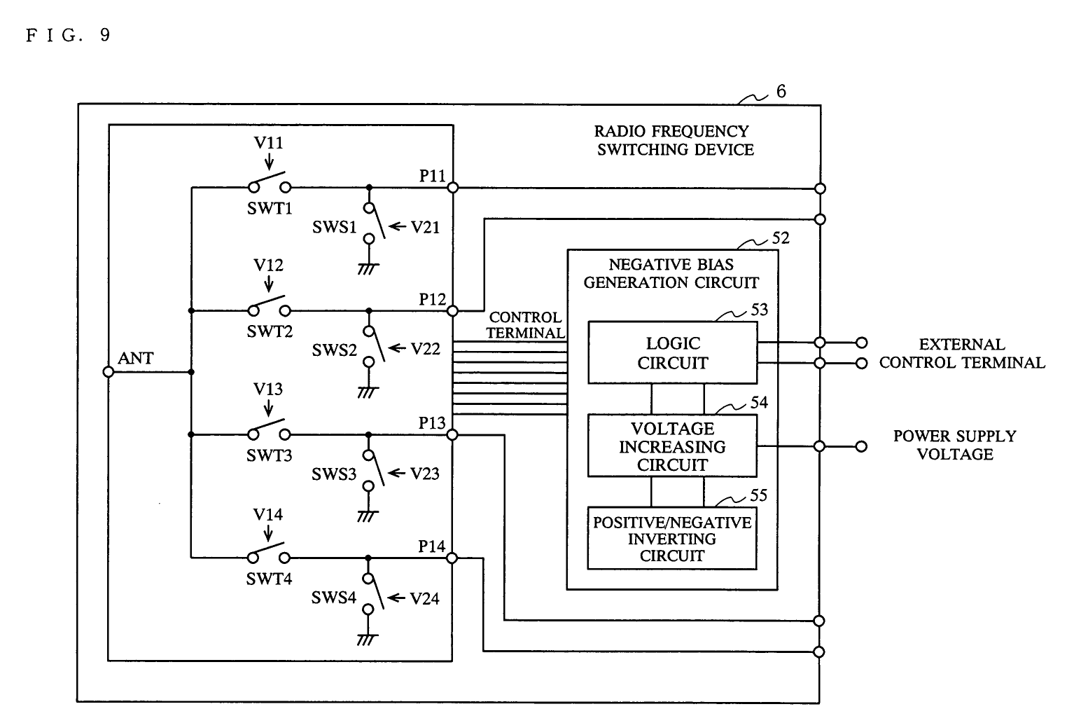

FIG. 9 shows a configuration of a radio frequency switching device 6 according to a sixth embodiment of the present invention. Referring to FIG. 9, the radio frequency switching device 6 includes a radio frequency switching circuit 61 and the negative bias generation circuit 52, which includes the logic circuit 53, the voltage increasing circuit 54 and the positive/negative inverting circuit 55 integrated together. As an example, the sixth embodiment shows the radio frequency switching device 6 being a SP4T radio frequency switch for a GSM/UMTS dual-mode mobile terminal. However, the embodiment can similarly be applied to radio frequency switches handling other signal amplitudes.

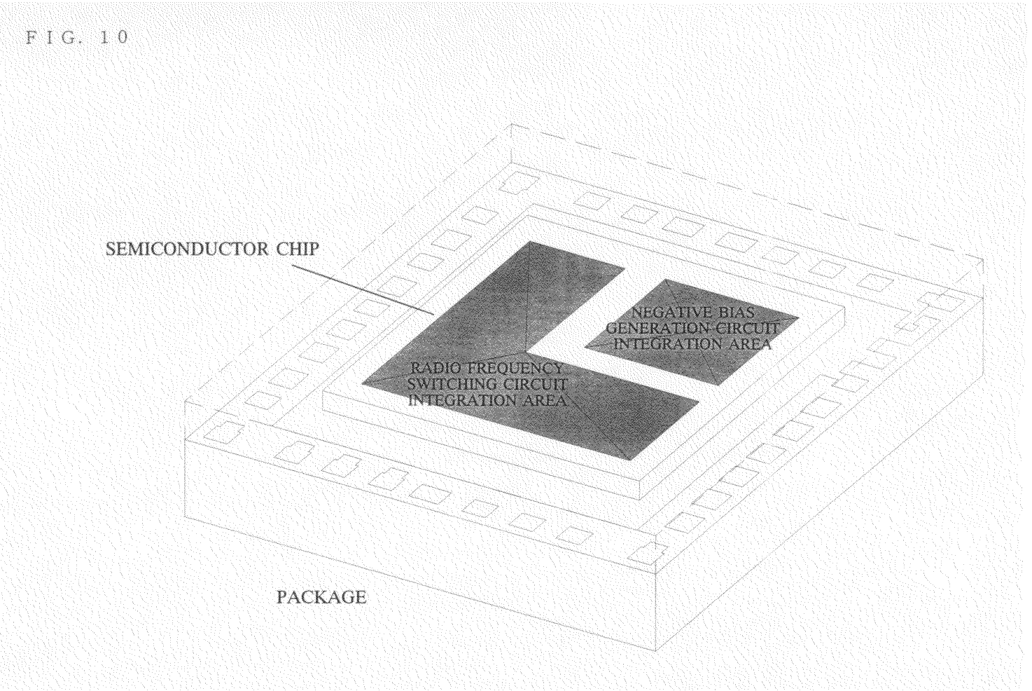

FIG. 10 is a perspective view showing an example of the inside of a package of the radio frequency switching device 6. As shown in FIG. 10, the radio frequency switching device 6 includes, in the form of bare chips packaged together, a semiconductor chip obtained by integrating the radio frequency switching circuit 61 and a semiconductor chip obtained by integrating the negative bias generation circuit 52.

The radio frequency switching circuit 61 includes transfer circuit sections SWT1 to SWT4 and shunt circuit sections SWS1 to SWS4. Four circuits each including a pair of a transfer circuit section SWTx and a shunt circuit section SWSx (where x is 1 to 4) are connected in parallel to one another, and each of these circuits is the radio frequency switching circuit 3 of the third embodiment. The number of the sets of transfer circuit sections and shunt circuit sections is not limited to four.

The inputs of the transfer circuit sections SWT1 to SWT4 are connected to an antenna connection terminal ANT. The first input/output terminal P11 is connected to a GSM (Global System for Mobile Communication) transmitter circuit section, and receives a signal of up to 35 dBm. The second input/output terminal P12 is connected to a GSM receiver circuit section, and outputs a signal of up to 10 dBm. The third and fourth input/output terminals P13 and P14 are connected to a UMTS (Universal Mobile Telecommunications System) transceiver circuit, and receives a signal of up to 26 dBm. The transfer circuit sections SWT1 to SWT4 and the shunt circuit sections SWS1 to SWS4 are controlled by the control terminals V11 to V14 and V21 to V24, respectively.

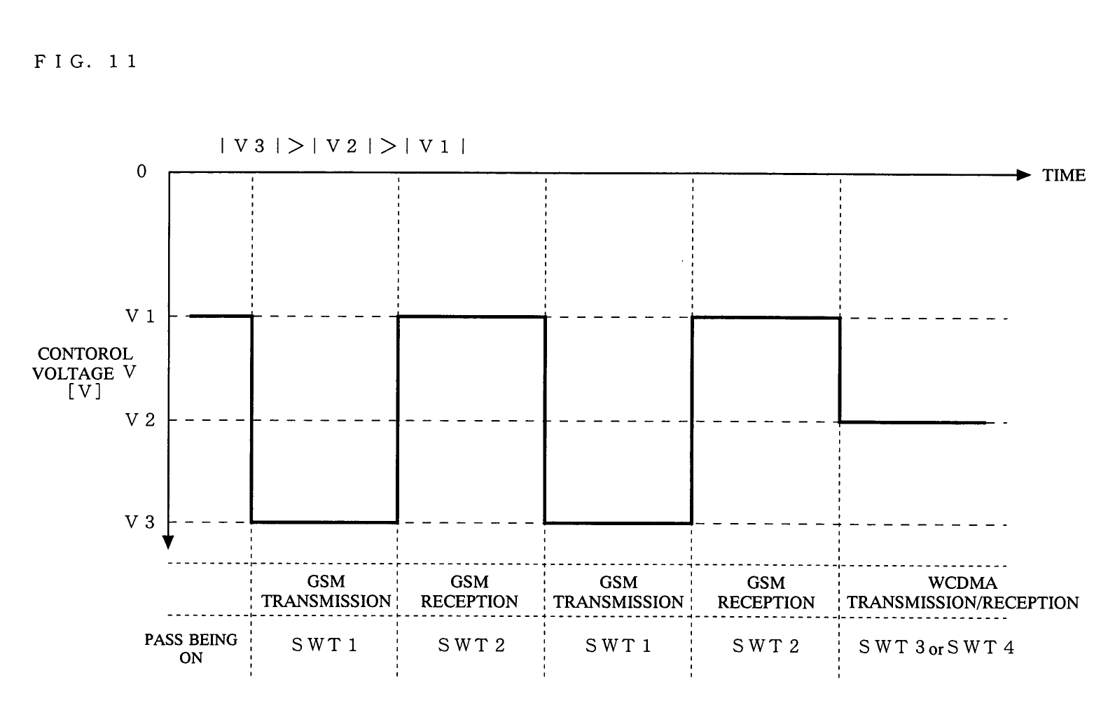

With the radio frequency switching device 6, the voltage level of the OFF control voltage of the control terminals V11 to V14 and V21 to V24 is changed as necessary by the external control voltage, as illustrated in FIG. 11. Thus, when a large signal is passing in a GSM transmission operation, each FET, which should be turned OFF, is reliably turned OFF by strongly reversely-biasing the gate-source (or gate-drain) voltage Vgs (or Vgd) thereof, thereby realizing desirable linearity and distortion characteristics. In a UMTS transmission operation, a signal as large as those used in a GSM transmission operation is not passed, and the signal in the UMTS transmission operation is actually about ⅓ of that in the GSM transmission operation in terms of the signal voltage amplitude, and the gate voltage resistance may be lower accordingly. Therefore, the reverse bias voltage of the gate-source (or gate-drain) voltage Vgs (or Vgd) of each FET does not have to be as large as that in a GSM transmission operation. Moreover, when a small signal is passed in a GSM reception operation, the voltage amplitude of the signal being passed is 1/10 or less. Therefore, the gate-source (or gate-drain) voltage Vgs (or Vgd) of each FET that should be turned OFF may be the lowest voltage possible with which the FET can be turned OFF. Therefore, the voltage-increasing function of the voltage increasing circuit 54 does not need to be turned ON, whereby no power consumption occurs in the voltage increasing circuit 54. The number of levels through which the voltage for the voltage-increasing function is varied is not limited to three, as shown in FIG. 11.

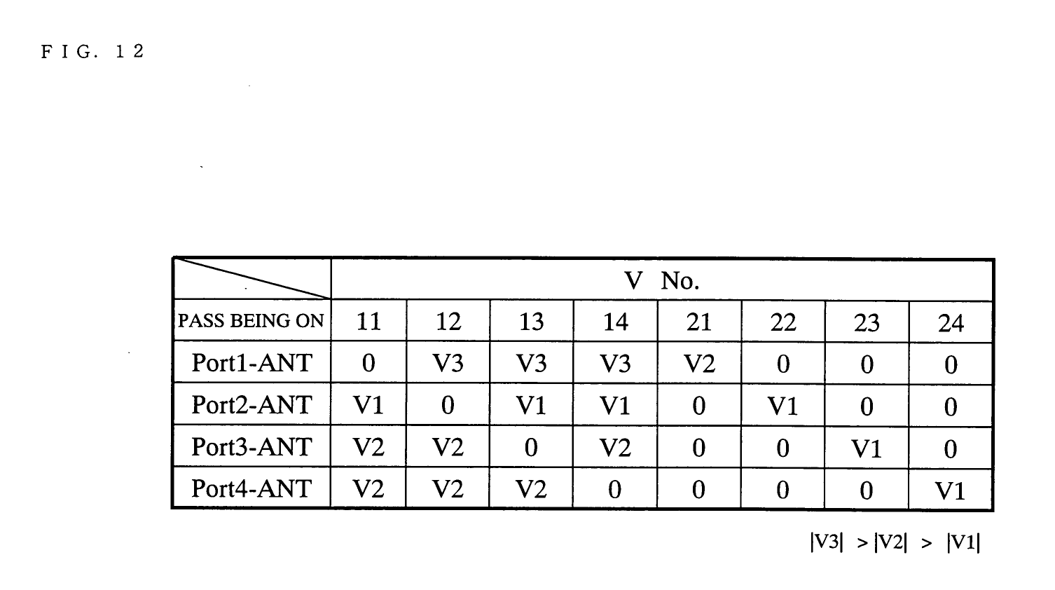

With the radio frequency switching device 6, when the device operates according to the control voltage applied to the control terminals V11 to V14 and V21 to V24 when the paths shown in FIG. 12 are ON, it is possible to reduce the number of FETs connected together in series with one another in the transfer circuit section to thereby reduce the ON resistance of the transfer circuit section, while increasing the number of FETs in the shunt circuit section to thereby reduce the OFF capacitance in the shunt FET section, thus realizing a reduction in the insertion loss of the radio frequency switching device.

As described above, with the radio frequency switching device 6 according to the sixth embodiment of the present invention, it is possible to realize a free-port radio frequency switching device by a control using a logic circuit, without changing the FET configuration, according to the amplitude of the signal to be passed therethrough.

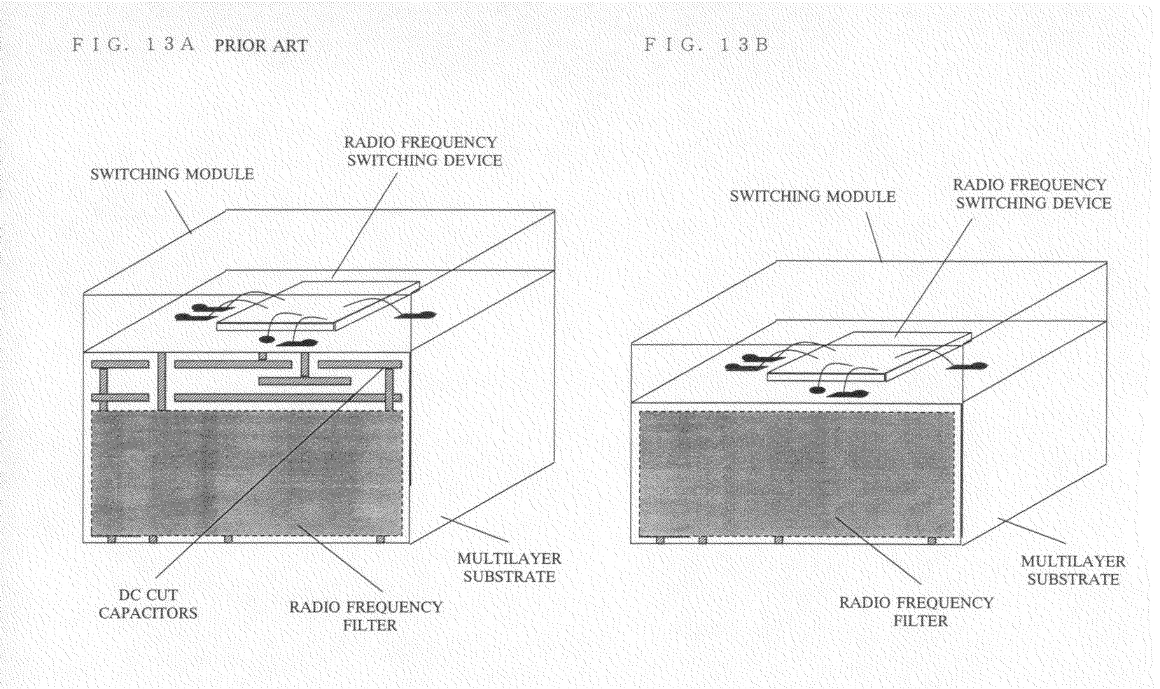

FIGS. 13A and 13B show cross-sectional perspective views each showing the inside of a package of a switching module in which a radio frequency filter is provided in a multilayer substrate as an example of the radio frequency switching device 6.

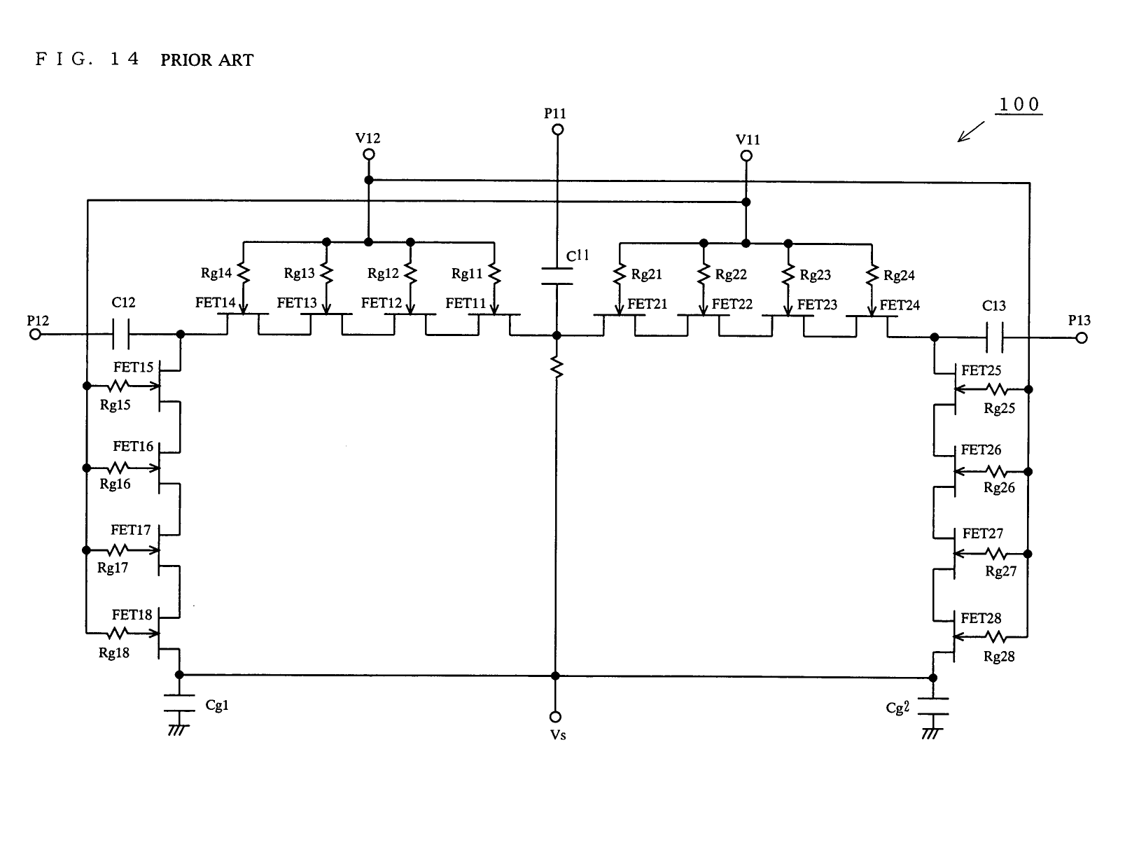

A conventional switching module shown in FIG. 13A in which a radio frequency filter is provided in a multilayer substrate includes grounded DC cut capacitors in the multilayer substrate in order to overcome the problem with the low ESD resistance due to the use of an MIM capacitor, as described above with the conventional radio frequency switching circuit (FIG. 14). Therefore, the conventional switching module has an increased substrate thickness and an increased physical volume due to the inclusion of DC cut capacitors in the multilayer substrate.

In contrast, the switching module shown in FIG. 13B using the radio frequency switching device 6 of the present invention and a multilayer substrate does not need DC cut capacitors provided in the multilayer substrate. Thus, it is possible to realize a package with a decreased height.

While the invention has been described in detail, the foregoing description is in all aspects illustrative and not restrictive. It is understood that numerous other modifications and variations can be devised without departing from the scope of the invention.

What is claimed is:

1. A radio frequency switching circuit for controlling a flow of a radio frequency signal, comprising:
at least one transistor connected together in series with one another and inserted between two input/output terminals for inputting/outputting the radio frequency signal;
a plurality of resistors for grounding a source and a drain of the at least one transistor via a predetermined resistance value; and
a plurality of gate resistors for applying a control voltage to a gate of the at least one transistor via a predetermined resistance value,
wherein either a negative bias voltage or a positive bias voltage being greater than or equal to 0V and less than or equal to a Schottky forward voltage is applied as the control voltage to turn ON/OFF the flow of the radio frequency signal.

2. A radio frequency switching circuit for controlling a flow of a radio frequency signal, comprising:
at least one transistor connected together in series with one another and inserted between an input/output terminal for inputting/outputting the radio frequency signal and a ground terminal;
a plurality of resistors for grounding a source and a drain of the at least one transistor via a predetermined resistance value; and
a plurality of gate resistors for applying a control voltage to a gate of the at least one transistor via a predetermined resistance value,
wherein either a negative bias voltage or a positive bias voltage being greater than or equal to 0V and less than or equal to a Schottky forward voltage is applied as the control voltage to turn ON/OFF the flow of the radio frequency signal.

3. A radio frequency switching circuit for controlling a flow of a radio frequency signal, comprising:
a plurality of transfer transistors, with at least one of the transfer transistors being connected together in series and inserted between a common input/output terminal for inputting/outputting the radio frequency signal and each of first to n-th input/output terminals;
a plurality of shunt transistors, with at least one of the shunt transistors being connected together in series and inserted between each of the first to n-th input/output terminals and a ground terminal;
a plurality of resistors for grounding sources and drains of the transfer transistors and the shunt transistors via a predetermined resistance value; and
a plurality of gate resistors for applying a plurality of different control voltages to gates of the transfer transistors and the shunt transistors via a predetermined resistance value,
wherein either a negative bias voltage or a positive bias voltage being greater than or equal to 0V and less than or equal to a Schottky forward voltage is applied as the plurality of different control voltages to turn ON/OFF the flow of the radio frequency signal.

4. A radio frequency switching device, comprising:
the radio frequency switching circuit according to claim 1; and
a negative bias generation circuit for generating the negative bias voltage, also having a function of increasing a level of a reference voltage applied from outside.

5. A radio frequency switching device, comprising:
the radio frequency switching circuit according to claim 2; and
a negative bias generation circuit for generating the negative bias voltage, also having a function of increasing a level of a reference voltage applied from outside.

6. A radio frequency switching device, comprising:
the radio frequency switching circuit according to claim 3; and
a negative bias generation circuit for generating the negative bias voltage, also having a function of increasing a level of a reference voltage applied from outside.

7. The radio frequency switching device according to claim 4, wherein the voltage level increasing function is able to be turned ON/OFF based on a path whose connection state is a DC circuit state.

8. The radio frequency switching device according to claim 5, wherein the voltage level increasing function is able to be turned ON/OFF based on a path whose connection state is a DC circuit state.

9. The radio frequency switching device according to claim 6, wherein the voltage level increasing function is able to be turned ON/OFF based on a path whose connection state is a DC circuit state.

10. The radio frequency switching device according to claim 4, wherein a level to which the reference voltage is increased is able to be selected based on a path whose connection state is a DC circuit state.

11. The radio frequency switching device according to claim 5, wherein a level to which the reference voltage is increased is able to be selected based on a path whose connection state is a DC circuit state.

12. The radio frequency switching device according to claim 6, wherein a level to which the reference voltage is increased is able to be selected based on a path whose connection state is a DC circuit state.

13. The radio frequency switching device according to claim 4, wherein a level to which the control voltage to be applied to the gate of each transistor is increased is able to be selected based on a path whose connection state is a DC circuit state.

14. The radio frequency switching device according to claim 5, wherein a level to which the control voltage to be applied to the gate of each transistor is increased is able to be selected based on a path whose connection state is a DC circuit state.

15. The radio frequency switching device according to claim 6, wherein a level to which the control voltage to be applied to the gate of each transistor is increased is able to be selected based on a path whose connection state is a DC circuit state.

16. The radio frequency switching device according to claim 4, wherein the radio frequency switching device is integrated on a semiconductor substrate.

17. The radio frequency switching device according to claim 5, wherein the radio frequency switching device is integrated on a semiconductor substrate.

18. The radio frequency switching device according to claim 6, wherein the radio frequency switching device is integrated on a semiconductor substrate.

19. The radio frequency switching device according to claim 16, wherein the transistors are metal-semiconductor field effect transistors.

20. The radio frequency switching device according to claim 17, wherein the transistors are metal-semiconductor field effect transistors.

21. The radio frequency switching device according to claim 18, wherein the transistors are metal-semiconductor field effect transistors.

22. The radio frequency switching device according to claim 16, wherein the transistors are metal-insulator-semiconductor field effect transistors.

23. The radio frequency switching device according to claim 17, wherein the transistors are metal-insulator-semiconductor field effect transistors.

24. The radio frequency switching device according to claim 18, wherein the transistors are metal-insulator-semiconductor field effect transistors.

25. The radio frequency switching device according to claim 4, wherein a semiconductor chip in which the transistors are formed and the negative bias generation circuit are provided in the same package.

26. The radio frequency switching device according to claim 5, wherein a semiconductor chip in which the transistors are formed and the negative bias generation circuit are provided in the same package.

27. The radio frequency switching device according to claim 6, wherein a semiconductor chip in which the transistors are formed and the negative bias generation circuit are provided in the same package.

28. The radio frequency switching device according to claim 4, wherein a semiconductor chip in which the transistors are formed and the negative bias generation circuit are formed on the same semiconductor substrate.

29. The radio frequency switching device according to claim 5, wherein a semiconductor chip in which the transistors are formed and the negative bias generation circuit are formed on the same semiconductor substrate.

30. The radio frequency switching device according to claim 6, wherein a semiconductor chip in which the transistors are formed and the negative bias generation circuit are formed on the same semiconductor substrate.

31. The radio frequency switching device according to claim 4, wherein the radio frequency switching device is mounted on a multilayer substrate.

32. The radio frequency switching device according to claim 5, wherein the radio frequency switching device is mounted on a multilayer substrate.

33. The radio frequency switching device according to claim 6, wherein the radio frequency switching device is mounted on a multilayer substrate.

34. A transmitter module device, comprising:
the radio frequency switching device according to claim 4; and
a power amplifier to which it is necessary to apply the negative bias voltage.

35. A transmitter module device, comprising:
the radio frequency switching device according to claim 5; and
a power amplifier to which it is necessary to apply the negative bias voltage.

36. A transmitter module device, comprising:
the radio frequency switching device according to claim 6; and
a power amplifier to which it is necessary to apply the negative bias voltage.
